(19) United States
(12) Patent Application Publication
(10) Pub. No.: US 2003/0213560 A1
(43) Pub. Date: Nov. 20, 2003

(54) Tandem wafer processing system and process

(76) Inventors: Yaxin Wang, Fremont, CA (US); Sean Michael Seutter, San Jose, CA (US); Xiaoliang Jin, San Jose, CA (US)

Correspondence Address: Patent Counsel, Applied Materials, Inc., P.O. Box 450A, Santa Clara, CA, 95052, US

(21) Appl. No.: 10/229,799

(22) Filed: Aug. 27, 2002

Related U.S. Application Data
(60) Provisional application No. 60/380,943, filed on May 16, 2002.

(51) Int. Cl. H01L 21/306; C23F 1/00; C23C 16/00

(52) U.S. Cl. 156/345.31; 118/719

(57) ABSTRACT

The present invention generally provides a cassette-to-cassette vacuum processing system which concurrently processes multiple wafers and combines the advantages of single wafer process chambers and multiple wafer handling for high quality wafer processing, high wafer throughput and reduced footprint. In accordance with one aspect of the invention, the system is preferably a staged vacuum system which generally includes a loadlock chamber for introducing wafers into the system and which also provides wafer cooling following processing, a transfer chamber for housing a wafer handler, and one or more processing chambers each having two or more processing regions which are isolatable from each other and preferably share a common gas supply and a common exhaust pump. The processing regions also preferably include separate gas distribution assemblies and RF power sources to provide a uniform plasma density over a wafer surface in each processing region. The processing chambers are configured to allow multiple, isolated processes to be performed concurrently in at least two processing regions so that at least two wafers can be processed simultaneously in a chamber with a high degree of process control.

### CROSS-REFERENCE TO RELATED APPLICATIONS

This application claims benefit of U.S. provisional patent application serial No. 60/380,943 filed May 16, 2002 which is herein incorporated by reference.

### FIELD OF THE INVENTION

The present invention relates to an apparatus, including a system and individual system components, for concurrent processing of multiple wafers in the fabrication of integrated circuits. More particularly, the present invention provides a staged vacuum system having one or more process chambers and corresponding lids which share one or more utilities, one or more loadlock chambers and a transfer chamber connected to both the loadlock chambers and the process chambers.

### BACKGROUND OF THE RELATED ART

The term “cluster tool” generally refers to a modular, multichamber, integrated processing system having a wafer handling module and a number of peripheral process chambers and a central data collection or process monitoring system. Cluster tools have become generally accepted as effective and efficient equipment for manufacturing advanced microelectronic devices to provide integrated devices that would not otherwise be produced by individual, isolated processes or hardware. Wafers are introduced into a cluster tool where they undergo a series of process steps sequentially in various process chambers to form integrated circuits. The transfer of the wafers between the process chambers on the same tool is typically managed by a wafer handling module located in a central transfer region. Typically, cluster tools form a process module and are of two different types: single wafer processing or batch wafer processing. Single wafer processing generally refers to a chamber configuration in which a single wafer is located for processing. A cluster tool configured for batch processing allows multiple wafers, typically ten or more wafers, to be simultaneously processed in a single tube chamber.

One disadvantage of batch processing, including the processing performed in the cluster tools described above, is that batch processing frequently provides poor wafer to wafer process repeatability depending upon the wafer loading position in the batch process apparatus. Wafers located in the central processing region may have film uniformity characteristics that are quite different than wafers located at the edge of the batch. As such, the process performance can be out of specification among the batch resulting in the need to discard some wafers because of low device yield.

As an example, when semiconductor device substrates shifted from 200 mm to 300 mm diameters, the available device surface area more than doubled. The total number of dies also nearly doubled. Therefore, the yield of the wafer nearly doubled as well. As such, if a 300 mm wafer process does not meet the required specifications, the cost of the fabrication production is doubled. Additionally, since the wafer size is increased, the total number of 300 mm wafers produced is reduced in comparison to 200 mm wafers. This phenomenon is particularly realized during initial process evaluation and device integration testing where the total number of 300 mm wafers to be processed will be significantly less. In a batch processing fabrication process, either a batch process apparatus has to operated in a partially loaded state (which results in low productivity) or be operated at a later date (when fully loaded) which results in product qualification delays.

High thermal budgets during the fabrication process are caused by high process temperatures combined with low deposition rates. Since batch processing usually yields a very low deposition rate, much longer process times are necessary to get desirable film thickness. Batch processing also requires process temperatures to be high enough to maintain a desirable deposition rate since deposition rate is directly proportional to process temperature. Furthermore, with the device size continuously decreasing (on the order of sub 100 nm), the thermal budget to process the wafer is critical to obtain fabricated devices that perform at or above desired specifications. For example, conventional batch processing temperatures are greater than 900C at processing times greater than one hour in comparison to modern fabrication techniques that only require processing temperatures less than 700C and processing times much less than one hour. In order to fabricate devices on the order of 65 nm, it will be necessary to lower processing temperatures to no more than 600C.

An alternative approach to improve wafer to wafer process uniformity is the use of single wafer processing chambers. Single wafer processing is generally considered to provide a higher degree of control over process uniformity (i.e., deposition rate, wafer temperature and the like), because a single wafer is positioned in a process chamber where it undergoes a complete process step, such as a deposition step or an etch step which is repeatable under the same process conditions and wafer loading position. Furthermore, the components of a single wafer processing chamber can be positioned concentrically or otherwise relative to the single wafer.

Improvements to single wafer processing chambers resulted in improved yield and device quality. Yet, the semiconductor processing industry continues to strive for larger production yields while enhancing the property of layers deposited on substrates having increasingly larger surface areas. These same factors in combination with new materials also provide higher integration of circuits per unit area of the substrate. As circuit integration increases, the need for better wafer to wafer repeatability and process control regarding layer thickness rises. As a result, various technologies have been developed to deposit layers on substrates in a cost-effective manner, while maintaining control over the characteristics of the layer. Chemical Vapor Deposition (CVD) is a common deposition process employed for depositing layers on a substrate. CVD requires precise control of the substrate temperature and precursors introduced into the processing chamber in order to produce a desired layer of uniform thickness. These requirements become more critical as substrate size increases, creating a need for more complexity in chamber design and fluid flow technique to maintain adequate uniformity.

Another deposition technique is atomic layer deposition (ALD). ALD has steps of chemisorption that deposit monolayers of reactive precursor molecules on a substrate surface. To that end, a pulse of a first reactive precursor is introduced into a processing chamber to deposit a first monolayer of molecules on a substrate disposed in the processing chamber. A pulse of a second reactive precursor is introduced into the processing chamber. The second reactant will react with the first monolayer to form a monolayer of film. In this manner, a layer is formed on a substrate by alternatingly pulsing an appropriate reactive precursor into a deposition chamber. Each injection of a reactive precursor is separated by an inert fluid purge to provide a new atomic layer additive to previous deposited layers to form a uniform layer on the substrate. The cycle is repeated to form the layer to a desired thickness. The control over the relatively small volume of gas utilized in each pulse is problematic. Pulse frequency is limited by the response times of valves and flow lag within the chamber's gas delivery system. The lag is at least partially due to the relative remote position of control valves to the process chamber thereby creating a “dead volume”. Additionally, flowpaths of reactive gases must be such that they can be delivered to the chamber (in close proximity to the substrate or wafer to be processed) so as to minimize the likelihood of deposition material formation on surfaces other than the substrate. That is, intermixing of the reactive gases prior to their introduction to the substrate surface should be minimized and if at all possible eliminated.

In the prior art, an LPCVD furnace with DCS (SiH₂Cl₂) and NH₃ precursors is the primary system used to make silicon nitride (SiNₓ) films that are currently used in Si-device integration. By running a batch process, the required throughput can be achieved with the furnace system. Disadvantages of the furnace system are i) high thermal budget—long time (typically 2-5 hours) at high temperatures (typically above 900C), and ii) low productivity—processing must wait until the furnace can be completely filled with wafers (typically 150 for 200 mm wafers). The scale-down of device design rules (<100 nm) will require low thermal budget for the SiNₓ process for various applications of transistors in logic and high performance SRAM devices. A single wafer CVD process product has been developed using chlorine-free SiH4/NH3 chemistry that is primarily used for relatively thick SiHₓ films for devices on the order of 100 nm and above. Such process delivers low in-film particle defects compared to DCS based batch furnace processes with low thermal budget. Although single wafer SiH4 based CVD processes can be continuously used for thick nitride film applications as blank film for devices on the order of 100 nm, the application for spacers is limited due to microloading, i.e., the pattern loading effect, which is limited by depletion of the reactant in the devised feature area of the wafer. Specifically, Pattern Loading Effect (PLE) is typically defined as the percentage of film thickness difference between a flat isolated area (usually thicker) and a dense structured area (usually thinner); therefore, the lower the percentage, the more uniform (and desirable) the film thickness across these areas. Similarly, step coverage (SC) is typically defined as the percentage of film thickness difference between the top surface of a feature and the bottom surface (or lower surfaces with respect to the top surface); therefore, the lower the percentage, the more uniform (and desirable) the film thickness in a single structure. SC usually becomes of greater concern as the Aspect Ratio (AR) of a particular structure increases to 4:1 and above.

ALD techniques provide highly conformal deposition with low PLE in comparison to other deposition techniques and nearly 100% step coverage. However, ALD processes generally result in a deposition rate that is much lower than typical CVD techniques. Improved productivity of the ALD process is essential to make ALD technology a production worthy process.

Therefore, there is a need for a vacuum processing system that provides both uniform wafer processing (i.e., PLE and SC and the like) and high throughput for SiNₓ layer formation for spacer applications in advance devices. More particularly, there is a need for an integrated system and process chambers incorporating single wafer architecture with batch wafer handling techniques with a low thermal budget. It would be desirable to have a system with a small footprint/faceprint and which requires lower capital investments and operating costs than typical cluster tools. It is also desirable for such a system to reduce the time required to deposit films employing sequential deposition techniques.

### SUMMARY OF THE INVENTION

The present invention provides an apparatus for processing wafers comprising a process chamber having two distinct processing regions; a lid disposed over and the process chamber; a substrate support disposed in each of the processing regions; and a chamber liner circumscribing each of the substrate supports thereby defining a gap between the chamber and the liner. The liner sealingly fits about a stem supporting the substrate support and may also be of multi-piece construction. Specifically, the liner has a bottom piece and a top piece where the bottom piece fits about a stem of the substrate support and radially extends outward therefrom. The top piece connects to the bottom piece at a right angle and circumscribes the substrate support.

The liner has at least one vacuum exhaust port. The construction of the liner and chamber is such that a purge gas can be flowed in the gap defined by the liner and the chamber.

A remote plasma cleaning unit disposed on top of the lid. The remote plasma cleaning unit is connected to a cleaning gas source and a purge gas source. Preferably, the cleaning gas source is NF3 and the purge gas source is inert gases or N2. Additionally, wherein the purge gas source continuously provides purge gas to the plasma cleaning unit.

The invention further includes details of the lid as being a lid body; a gas distributor disposed in a recess in the lid body; and a faceplate disposed below the gas distributor. The lid further comprises openings to allow connection of the lid to two reactant gases. Two reactant chemical species are controlled by 3-port valves to generate pulsed and alternating injection of the reactants. Specifically, the openings comprise a first channel fluidly connected to a first set of openings and a second channel fluidly connected to a second set of openings wherein neither the first and second channels nor the first and second set of openings are fluidly interconnected. The lid body further comprises heat transfer passages disposed therein.

### BRIEF DESCRIPTION OF THE DRAWINGS

The above and other advantages of the present invention are described in conjunction with the following drawing figures, in which:

FIG. 1 is a perspective view of one embodiment of the vacuum processing system of the present invention;

FIG. 2 is a top schematic view of one embodiment of the vacuum processing system of the present invention;

FIG. 3 is a perspective view of one embodiment of the vacuum processing system of the present invention with two modular frames removed;

FIG. 4 is a top view of one embodiment of the vacuum processing system of the present invention similar to that shown in FIG. 3;

FIG. 5 is a substantially front perspective view of the inside of a loadlock chamber of the present invention;

FIG. 5A is a perspective view of another embodiment of a loadlock chamber of the present invention;

FIG. 6 is a top view of the present invention similar to that shown in FIG. 1;

FIG. 7 is a cross sectional side view of a transfer chamber of the present invention;

FIG. 8 is a top view of a transfer chamber and a twin processing chamber showing a wafer handling member of the present invention mounted in the transfer chamber and in a retracted position ready for rotation within the transfer chamber or extension into another chamber;

FIG. 9 is a perspective view of one embodiment of the twin processing chamber of the present invention;

FIG. 10 is a cross sectional view of one embodiment of the twin processing chamber of the present invention;

FIG. 11 is a top view of the twin processing chamber of the present invention with the lid removed;

FIG. 12 is a perspective view of a modular frame unit housing the twin processing chamber of the present invention;

FIG. 13 is a cross-sectional view of one of the processing regions of the twin processing chamber of the present invention;

FIG. 14 is a detailed cross-sectional view of the chamber lid of the present invention;

FIG. 15 is a perspective view of the detailed hardward and lid of the present invention;

FIG. 16 is a schematic diagram of the gas distribution network of the present invention;

FIG. 17 is a schematic diagram detailing the purging line network of the present invention;

FIG. 18 is a schematic diagram of a vacuum system of the present invention; and

FIG. 19 is an illustrative block diagram of the hierarchical control structure of a computer program for process control of the present invention.

### DETAILED DESCRIPTION OF THE INVENTION

The present invention generally provides a cassette-to-cassette vacuum processing system which concurrently processes multiple wafers and combines the advantages of single wafer process chambers and multiple wafer handling for high quality wafer processing, high wafer throughput and reduced system footprint. In accordance with one aspect of the invention, the system is preferably a staged vacuum system which generally includes a loadlock chamber for introducing wafers into the system and which also provides wafer cooling following processing, a transfer chamber for housing a wafer handler, and one or more processing chambers each having two or more processing regions which are isolatable from each other and preferably share a common gas supply and a common exhaust pump. Isolatable means that the processing regions have a confined reaction zone separate from the adjacent region which is selectively communicable with the adjacent region via an exhaust system. The processing regions within each chamber also preferably include separate gas distribution assemblies and thermal control systems including uniform temperature control from a heater in each processing region. The processing chambers are configured to allow multiple, isolated processes to be performed concurrently in at least two regions so that at least two wafers can be processed simultaneously in separate processing regions with a high degree of process control provided by shared gas sources, shared exhaust systems, separate gas distribution assemblies, separate heaters, and separate temperature control systems. For ease of description, the term processing regions of a chamber may be used to designate the zone in which deposition processing is carried out.

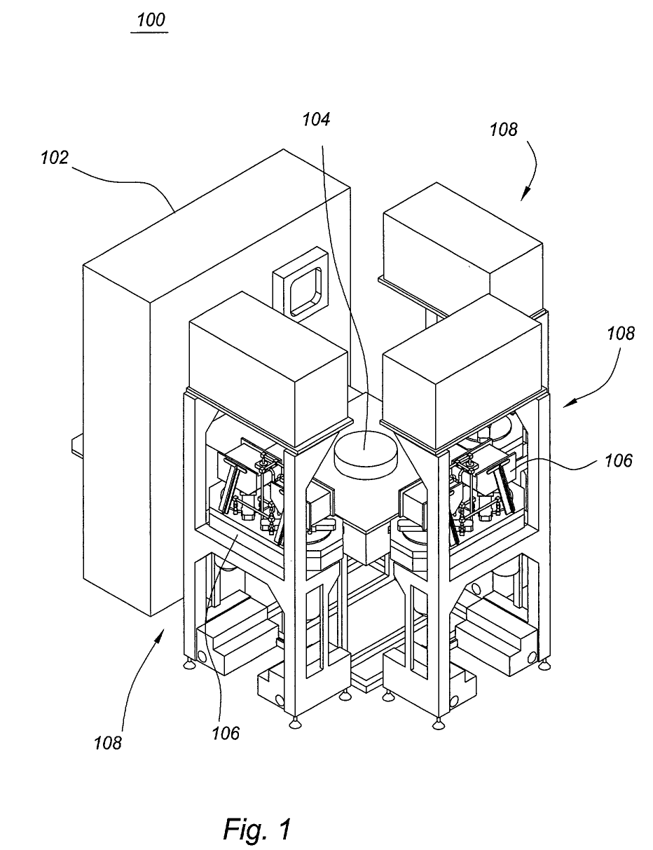

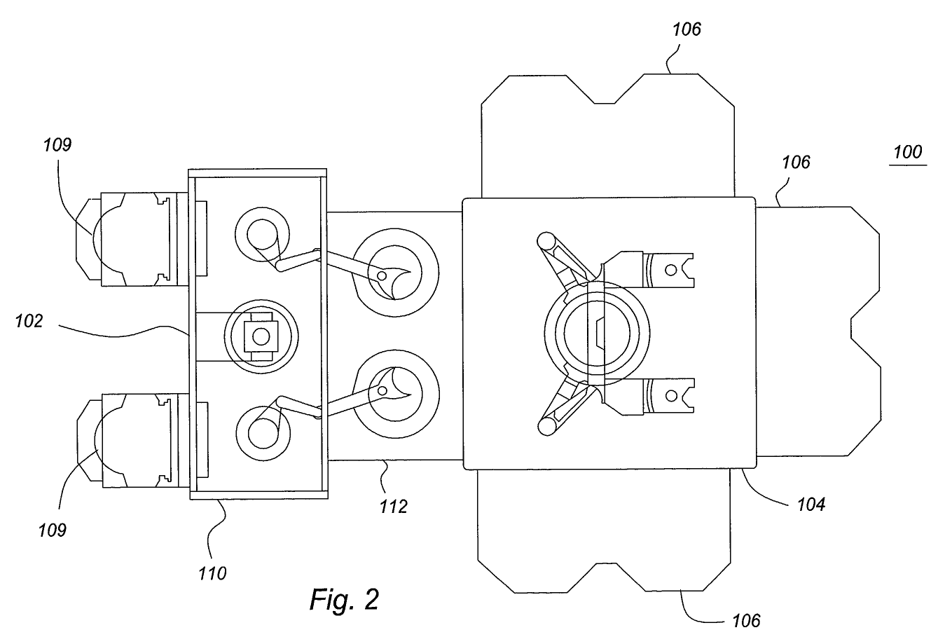

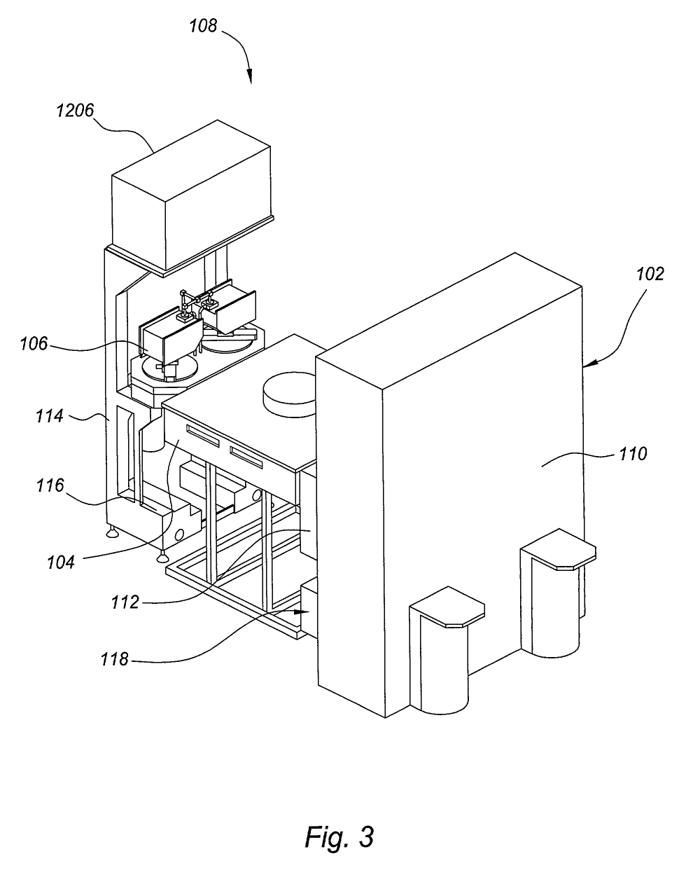

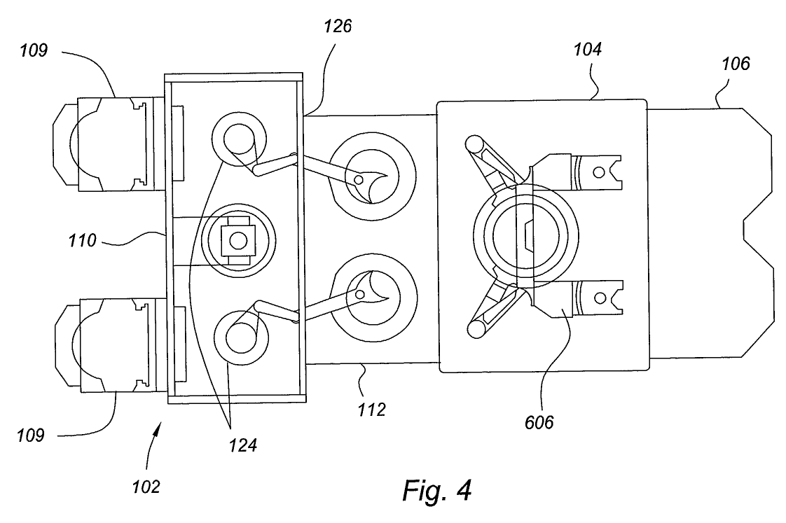

FIGS. 1-4 illustrate the processing system 100 of the present invention schematically. The system 100 is a self-contained, modular system having the necessary processing components as described in detail below which are easily installed thereby providing a quick start up for operation. The system 100 generally includes three different regions, namely, a front end staging area 102 where wafer cassettes 109 (shown in phantom in FIGS. 2 and 4) are supported and wafers are loaded into and unloaded from a loadlock chamber 112, a transfer chamber 104 housing a wafer handler 612 (described in greater detail below) and a series of tandem process chambers 106 mounted on the transfer chamber 104 via a series of modular process chamber frames 108. The system can be adapted to accommodate various processes and supporting chamber hardware such as CVD, PVD and etch. The embodiment described below will be directed to a system employing a dielectric deposition process, such as a silane process, to deposit silicon nitride by chemisorbtion (ALD). However, it is to be understood that these and other processes are contemplated by the present invention.

Front End Staging Area

FIGS. 2, 3 and 4 collectively show the front end staging area (or Factory Interface) 102 of the system 100 which includes a staging platform 110 to support one or more wafer cassettes 109 for processing. Wafers housed in the wafer cassettes 109 are loaded into the system 100. A front end wafer handler 124, such as a dual blade robot, is mounted on the staging platform 110 adjacent a loadlock chamber loading port 126. Preferably, the front end wafer handler 124 includes a wafer mapping system to index the wafers in each wafer cassette 109 in preparation for loading the wafers into a loadlock cassette disposed in the loadlock chamber 112. The loadlock chamber 112 may be single or multiple wafer in configuration and acts as a staging area either for wafers to be picked up and processed (i.e., they can be manipulated by transfer chamber robot 612 in the transfer chamber 104 and into a process chamber 106 as described in greater detail below) or for wafers to be examined during processing diagnostics and monitoring. Diagnostic data is collected and passed on to a central control system of the fabrication facility. Additionally, a mainframe AC box 118 is positioned below the loadlock chamber 112 for supplying AC power to system components such as those of the front end staging area 102. Similarly, a process chamber AC box 116 is provided below each twin processing chamber 106 for supplying AC power to system components such as the twin processing chamber and attendant equipment. A mainframe control box (not shown) is typically located above the loadlock chamber 112 for controlling electronic components of the system 100. A chamber control module 114 is provided below each twin processing chamber 106 to assist in the processing of digital signals and data to the mainframe control box. For example, the chamber control module 114 is a DNET (DeviceNet) system of hardware and software capable of digital signal processing for the control of, for example but not limited to, MFC's, chamber pressure regulators, temperature control devices, EC valves and the like. Such as system is commercially available.

Loadlock Chamber

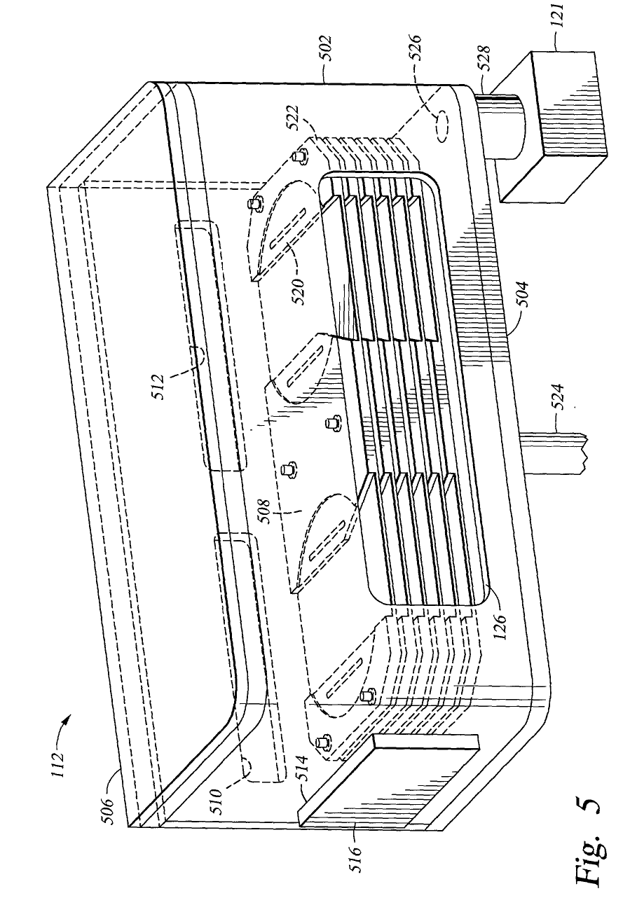

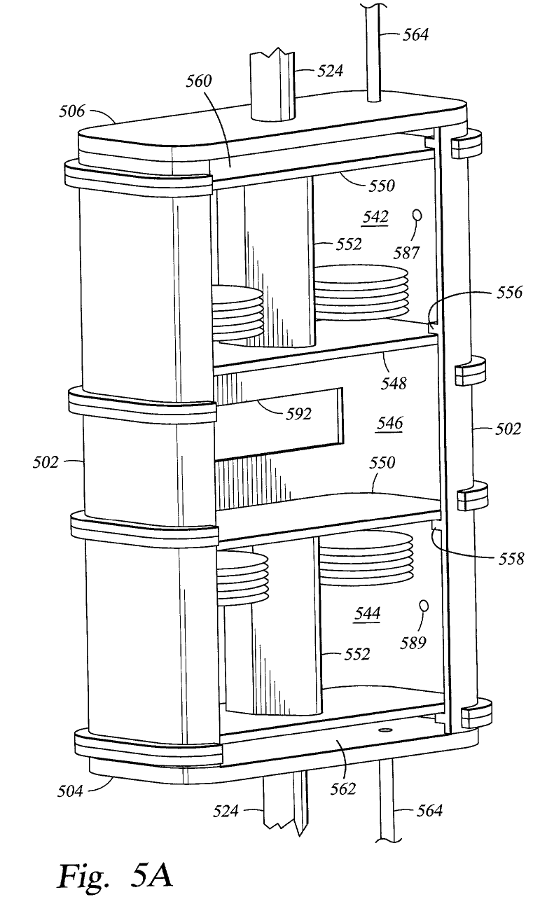

FIG. 5 shows a substantially side perspective and top view of one embodiment of a loadlock chamber 112 of the present invention. The loadlock chamber 112 includes a sidewall 502, a bottom 504 and a lid 506. The sidewall 502 defines the loadlock loading port 126 for loading wafers into and unloading wafers out of the processing system 100. Passages 510 and 512 are disposed in the sidewall 502 opposite the loading port 126 to allow wafers to be moved from the loadlock chamber 112 into the transfer chamber 104 (FIGS. 1 and 2). Slit valves and slit valve actuators (not shown) are used to seal the passages 510 and 512 when isolation or staged vacuum is desired. A service port 514 and service door or window 516 are disposed on one end of the loadlock chamber 112 to provide service and visual access to the loadlock chamber 112.

A loadlock cassette 508 is disposed within the loadlock chamber 112 to support the wafers in a spaced relationship in the loadlock chamber 112 so that the wafer handler can pass between the wafers to place and remove wafers from the loadlock cassette 508. The loadlock cassette 508 preferably supports two or more wafers in a side-by-side arrangement on wafer seats 520. The wafer seats 520 are formed on cassette plates 522 which are supported in spaced relation on a movable shaft 524.

The shaft 524 is disposed through the bottom 504 of the loadlock chamber 112 and supports the cassette plates 522 within the loadlock chamber 112. A motor (not shown), such as a stepper motor or other elevator system, is disposed below the bottom 504 of the loadlock chamber 112 and moves the shaft 524 upwardly and downwardly within the loadlock chamber 112 to locate a pair of wafers in alignment with a wafer handler for loading or unloading wafers from the loadlock chamber 112.

An on-board vacuum pump 121 is attached to the system 100 adjacent the loadlock chamber 112 and the transfer chamber 104 to pump down those components. An exhaust port 526 is disposed through the bottom of the loadlock chamber 112 and is connected to the pump 121 via exhaust line 528. The pump is preferably a high vacuum turbo pump capable of providing milliTorr pressures with very low vibration. The transfer chamber 104 is preferably pumped down through the loadlock chamber 112 by opening the pair of passages 510, 512 and pumping gases out through the exhaust port 526 located in the loadlock chamber 112. Gas-bound particles are kept from being swept into the transfer chamber 104 by continually exhausting gases out of the system through the loadlock chamber 112.

Dual Position Loadlock Chamber

FIG. 5A shows a cut-away perspective view of another embodiment of a loadlock chamber 112 of the present invention. The loadlock chamber 112 includes chamber walls 502, a bottom 504, and a lid 506. The chamber 112 includes two separate environments or compartments 542, 544 and a transfer region 546. Compartments 542, 544 each include a wafer cassette (not shown for sake of clarity, but otherwise similar to 508 of FIG. 5 and designed to carry a single stack of wafers) to support the wafers therein. Each compartment 542, 544 includes a support platform 548 and a top platform 550 to define the bottom and top of the compartments 542, 544. A support wall 552 may be disposed vertically within the compartments 542, 544 to support platforms 548, 550 in a spaced relationship. Transfer region 546 includes one or more passages 592 for providing access from the loadlock chamber 112 into the transfer chamber 104 (not shown). Passages 592 are preferably opened and closed using slit valves and slit valve actuators.

Compartments 542, 544 are each connected to an elevator shaft 524, each of which is connected to a motor, such as a stepper motor or the like, to move the compartments upwardly or downwardly within the loadlock chamber 112. A sealing flange 556 is disposed peripherally within the loadlock chamber 112 to provide a sealing surface for support platform 548 of compartment 542. Sealing flange 558 is similarly disposed to provide a sealing surface for support platform 550 of compartment 544. The compartments 542, 544 are isolated from one another by sealing flanges 556, 558 to provide independent staged vacuum of the compartments 542, 544 within the loadlock chamber 112.

A back side pressure is maintained in spaces 560, 562 through a vacuum port disposed therein. A vacuum pump is connected to the spaces 560, 562 via exhaust lines 564 so that a high vacuum can be provided in the spaces 560, 562 to assist in sealing the platforms 548, 550 against the sealing flanges 556, 558.

In operation, compartments 542, 544 can be loaded or unloaded in the position shown in FIG. 5A. Loading doors and actuators, are provided through the front wall (not shown) at the upper and lower limits of the loadlock chamber 112 correspond with compartments 542, 544. The pressure in a selected compartment is pumped down after wafers have been loaded into the compartment via exhaust lines 587, 589 and the selected compartment is moved into the transfer region 546. Compartments 542, 544 move independently into the transfer region 546 by the stepper motor. The advantage of having upper and lower compartments 542, 544 is that processing of one set of wafers can occur while a second set of wafers is loaded into the other compartment and that compartment is pumped down to the appropriate pressure so that the compartment can be moved into the transfer region 546 and in communication with the transfer chamber 104.

Transfer Chamber

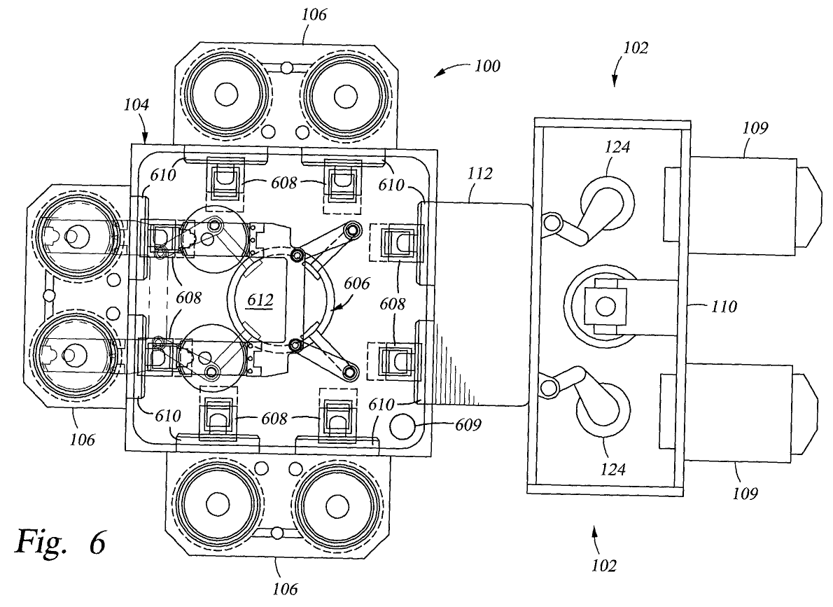

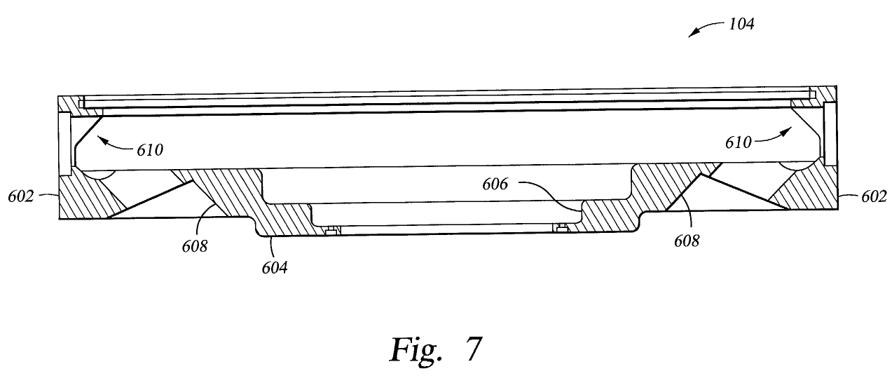

FIGS. 6 and 7 show a top view and a partial cross-sectional view respectively of the transfer chamber 104 of the processing system 100 of the present invention. More specifically, FIG. 6 shows a transfer chamber 104 having a transfer wafer handling member 606 located therein and a front end platform (Factory Interface) 102 having two wafer stages and a front end wafer handling member mounted thereon for wafer mapping and centering. The transfer chamber body includes sidewalls 602 and bottom 604 and is preferably machined or otherwise fabricated from one piece of material, such as aluminum. A lid (not shown) is supported on the sidewalls 602 during operation to form a vacuum enclosure. The sidewall 602 of transfer chamber 104 supports processing chambers 106 and loadlock chamber 112. The sidewall 602 defines at least two passages 610 on each side through which access to the other chambers on the system is provided. Each of the processing chambers 106 and loadlock chamber 112 include one or more slit valve openings (e.g., passages 510 and 512) and slit valves which enable communication between the processing chambers, the loadlock chamber and the transfer chamber while also providing vacuum isolation of the environments within each of these chambers to enable a staged vacuum within the system. The bottom 604 of the transfer chamber 104 defines a central passage 606 in which a wafer handler 612, such as a robot assembly, extends and is mounted to the bottom of the transfer chamber 104. In addition, the bottom 604 defines a plurality of passages 608 through which one or more slit valve actuators extend and are sealably mounted. A gas purge port 609 is disposed through the bottom 604 of the transfer chamber 104 to provide a purge gas during pump down. The passages 610 disposed through the sidewalls 602 can be opened and closed using two individual slit valves or a tandem slit valve assembly. Slit valves and methods of controlling slit valves are disclosed by Tepman et al. in U.S. Pat. No. 5,226,632 and by Lorimer in U.S. Pat. No. 5,363,872, both of which are incorporated herein by reference. The passages 610 mate with the wafer passages of process chambers as described in greater detail below.

Transfer Chamber Wafer Handler

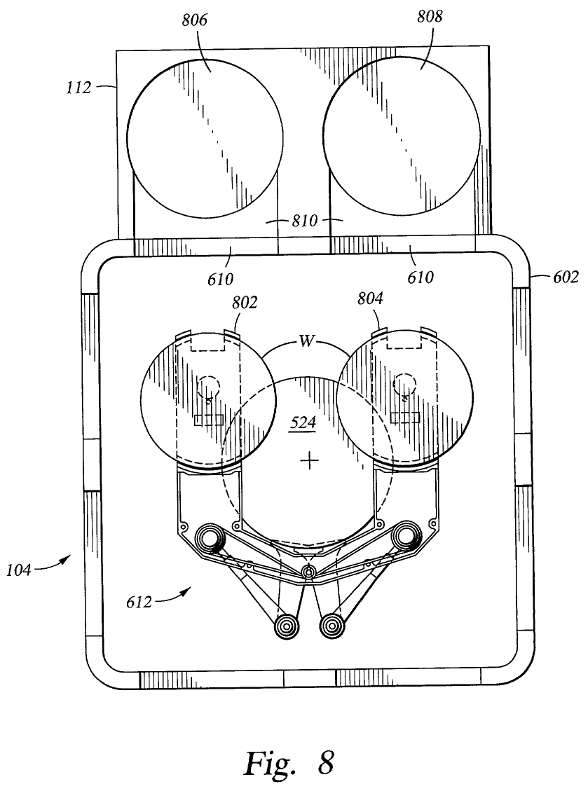

FIG. 8 shows a top schematic view of the wafer handler 612 (i.e., a magnetically coupled robot) of the present invention in a retracted position for rotating freely within the transfer chamber 104. A robot having dual wafer handling blades 802, 804 is located within the transfer chamber 104 to transfer the wafers W from one chamber to another. An example of the type of robot which can be modified and used to advantage in the present invention is disclosed in U.S. Pat. Nos. 5,838,121 issued Nov. 17, 1998 to Fairbairn et al. and 5,855,681 issued Jan. 5, 1999 to Maydan et al. and are incorporated herein by reference. The magnetically coupled wafer handler (robot) 612 comprises a frog-leg type assembly connected between two vacuum side hubs (also referred to as magnetic clamps) and dual wafer blades 802, 804 to provide both radial and rotational movement of the robot blades within a fixed plane. Radial and rotational movements can be coordinated or combined in order to pickup, transfer and deliver two wafers from one location within the system 100 to another, such as from one processing chamber 106 to another chamber 106.

Two wafers W are shown loaded on the wafer handler 612 to illustrate that the individual wafer blades 802, 804 can be extended through individual wafer passages 610 in sidewall 602 of the transfer chamber 104 and through process chamber wafer passages 810 to transfer the wafers W into or out of processing regions 806, 808 of the process chambers 106 (as denoted by arrows).

Process Chambers

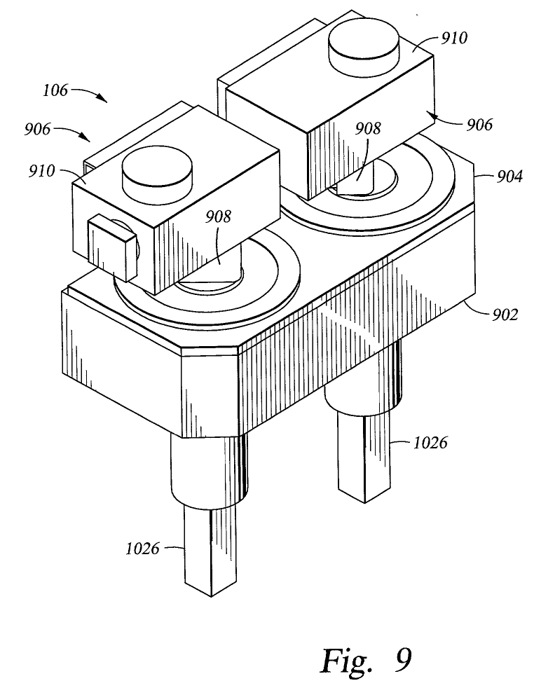

FIG. 9 shows a perspective view of one embodiment of a tandem processing chamber 106 of the present invention. Chamber body 902 is mounted or otherwise connected to the transfer chamber 104 and includes two processing regions in which individual wafers are concurrently processed. The chamber body 902 is fabricated from aluminum or an aluminum alloy and preferably LP aluminum alloy. The chamber body 902 supports a lid 904 which is hindgedly attached to the chamber body 902 and includes one or more gas distribution systems 906 disposed therethrough for delivering reactant and cleaning gases into processing regions 806/808 of FIG. 8. Details regarding the specific construction and design of the lid 904 and gas distribution system 906 are provided below.

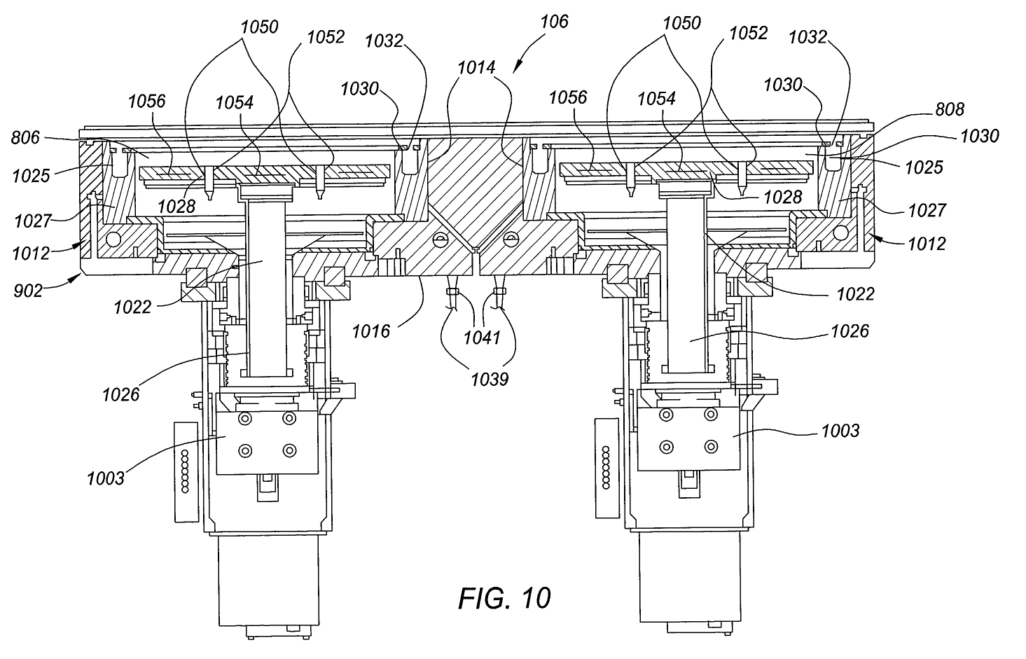

FIG. 10 shows a schematic cross-sectional view of the tandem (or twin) processing chamber 106 defining the two aforementioned processing regions 806, 808. Chamber body 902 includes sidewall 1012, interior wall 1014 and bottom wall 1016 which define the two processing regions 806, 808. The bottom wall 1016 defines a plurality of lower passages 1022 (e.g., one lower passage per processing region) through which a stem 1026 of a pedestal heater 1028 are disposed.

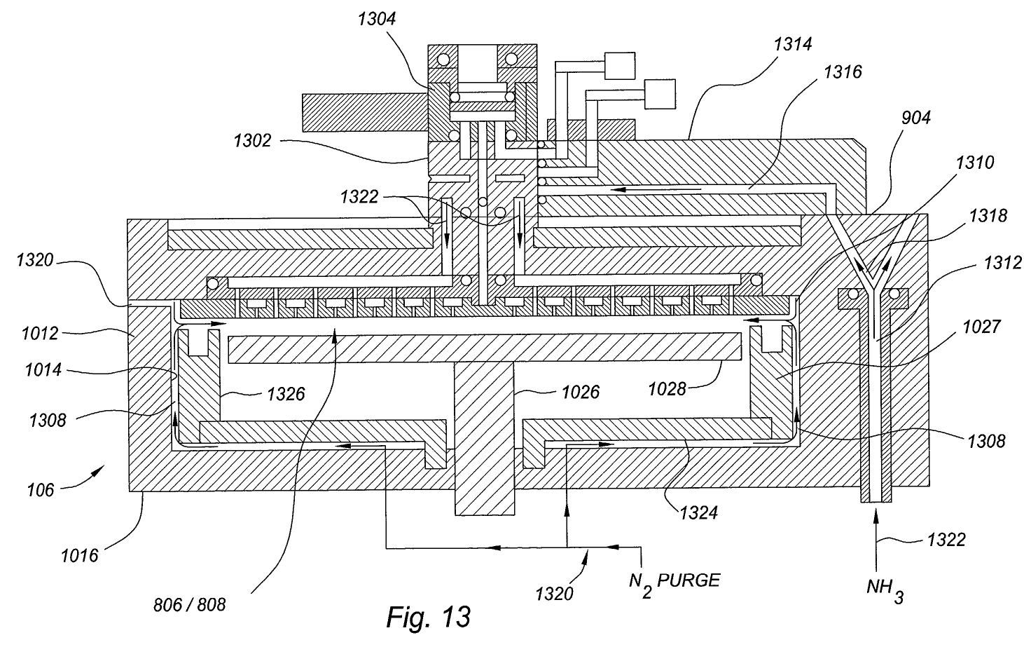

The sidewall 1012 and the interior wall 1014 define two cylindrical annular processing regions 806, 808. A circumferential pumping channel 1025 is built in the chamber liner circumscribing the cylindrical processing regions 806, 808 for exhausting gases from and controlling the pressure within the processing regions 806, 808. A pumping plate 1030 is disposed on top of the pumping channel 1025 and is provided with a plurality of pumping holes 1032. Chamber atmosphere is exhausted by pulling a vacuum (via an exhaust pump) through the pumping holes 1032, pumping channel 1025 to a chamber exhaust system described in greater detail below. A chamber liner or insert 1027, preferably made of ceramic or LP Aluminum the like, is disposed in each processing region 806, 808 to define the lateral boundary of each processing region and to protect the chamber walls 1012, 1014 from the corrosive processing environment. Additionally, the walls can be anodized to further protect against corrosion. The liner 1027 is described in greater detail below with respect to FIG. 13.

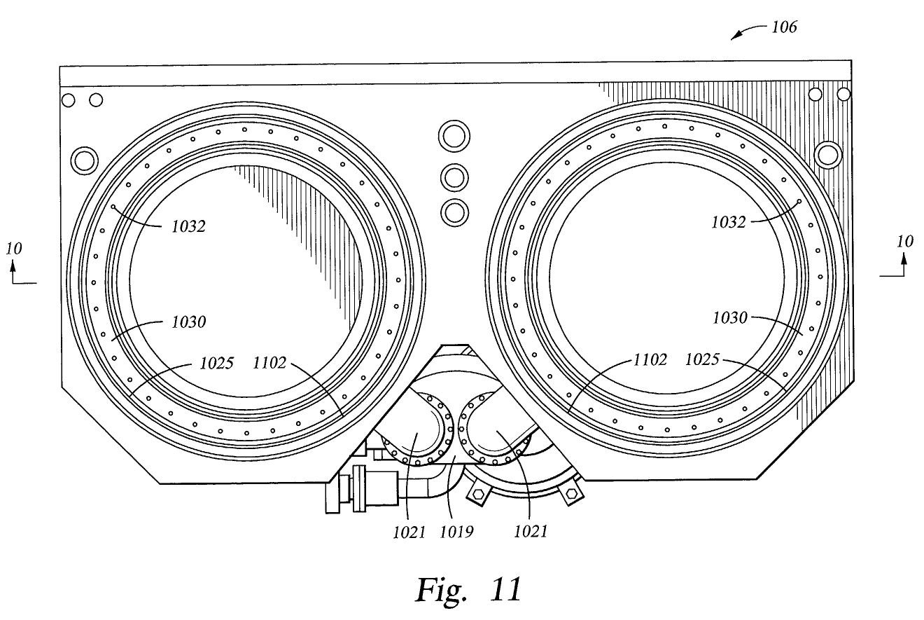

FIG. 11 shows a cross sectional view of the chamber illustrating the exhaust system of the present invention. The pumping channels 1025 of each processing region 806, 808 are preferably connected to a common exhaust pump via a common exhaust channel 1019. The exhaust channel 1019 is connected to the pumping channel 1025 of each region 806, 808 by exhaust conduits 1021. A seal 1102 is disposed between each pumping channel 1025 and each exhaust conduit 1021. Such seal 1102 prevents deposition upon the inner chamber walls 1014 and also prevents a non-uniform (i.e. non-linear) purge gas flow. The exhaust channel 1019 is connected to an exhaust pump via an exhaust line (not shown). Each region is preferably pumped down to a selected pressure by the pump and the connected exhaust system allows equalization of the pressure within each region.

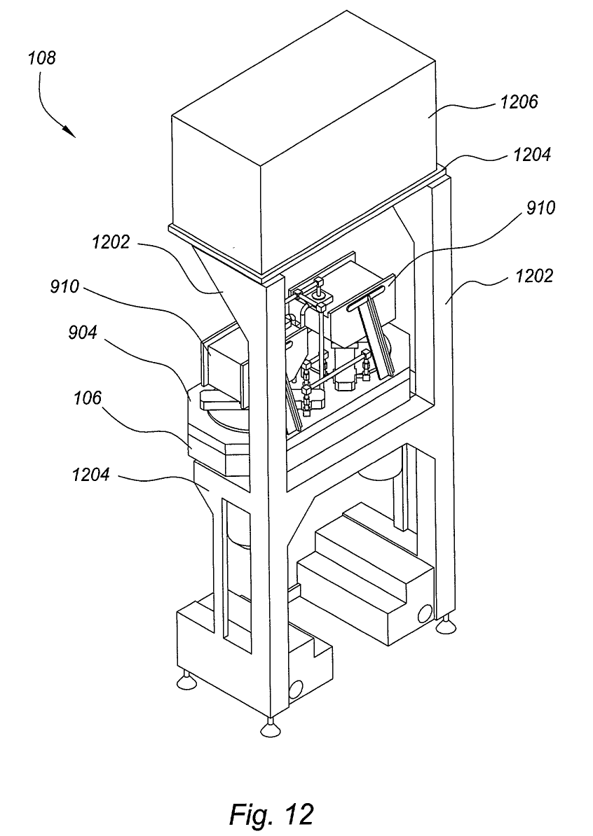

One specific and desired embodiment of the system 100 contains a specially designed modular frame capable of being quickly and easily assembled onto the transfer chamber 104 to connect processing chambers 106 and their attendant components. FIG. 12 depicts such a frame 108 in detail and is part of the Producer SE fabrication unit manufactured and sold by Applied Materials, Inc. of Santa Clara, Calif. Specifically, the frame 108 is formed from a plurality of upright members 1202 and transverse members 1204 properly sized and interfitted so as to support the processing chamber 106, lid 904 and cleaning plasma generators 906. A gas panel 1206 is disposed atop the cleaning plasma generators 906 and supported by the frame 108. The gas panel 1206 provides the necessary routing and plumbing of process (reactive, purge, cleaning and the like) gases from facilities connections (not shown) to the dedicated processing chamber 106 therebelow. Such a modular unit of the gas panel and processing chamber saves valuable time in the initial assembly of the system and facilitates eventual separation of the components for repair, replacement and the like. For sake of clarity, it should be noted that the frame 108 and gas panel 1206 do not appear in FIGS. 2, 4 and 6 so as to more clearly make out the components (transfer chamber 106 and processing chambers 104) that would otherwise have been obscured from view.

FIG. 13 depicts a cross-sectional view of one of the processing regions 806/808 of the processing chamber 106. Atop the lid 904 is a central manifold 1302 for distributing gases from the gas panel 1206 (not pictured) to the processing regions 806/808. Atop the central manifold 1302 is a gate valve 1304 that separates a plasma cleaning unit 910 during processing to reduce chamber volume. The central manifold is plumbed to one or more purge sources X and Y and is described in greater detail below.

A longitudinally extending portion 1314 of the central manifold 1302 contains a conduit 1316 for chamber purging. More specifically, the outer chamber wall 1012 and inner chamber wall 1014 define a wall conduit 1312 that fluidly connects to the central manifold conduit 1316 via a lid conduit 1318. Process gas from a process gas source is fed into the central manifold 1302, through conduits 1316,1318 and 1312 and introduced into the chamber 106 as denoted by flow arrows 1322. The liner 1027 is circumferentially disposed about the pedestal support 1026. The liner 1027 extends radially inward towards the pedestal heater stem 1028. The liner is so shaped and sized so as to define a gap 1308 between the liner 1027, the inner chamber wall 1014 and chamber bottom wall 1016 yet maintain a good seal between the chamber 106 and exhaust port (not shown). Additionally, the liner 1027 is self-centering. Specifically, as the temperature of the chamber increases to processing temperatures (approximately 150-200C), the liner 1027 will expand uniformly in all directions. Accordingly, there will be no shifting of chamber components caused by unexpected thermal expansion and the seal created by the liner 1027 will remain intact during processing. In this way, liner purge gas enters from the bottom of the chamber 106 into the gap 1308 and flows radially outward and then upward to the processing region 806/808. The liner also assists in preventing deposition of material in unwanted areas of the chamber 106 by acting as a thermal barrier. That is, the liner is selected from a material of the group consisting of aluminum (such as LP aluminum or other alloys) plus a coating material and ceramic. In a preferred embodiment of the invention, the liner 1027 further comprises a bottom piece 1324 and a top piece 1326. The bottom piece 1324 horizontally extends along the chamber bottom wall 1016 inside the chamber. The top piece 1326 meets and fits the bottom portion 1324 and rises up along the inner chamber wall 1014. Faceplate purge ports 1320 are created by a gap between the lid 904 and the chamber body 902. The purge ports 1320 define a space for the flow of purge gas to travel to prevent deposition of or undesirable gas flow near these chamber components as described in greater detail below.

Such material retain a sufficient amount of heat generated by the chamber so as to keep the temperature at approximately the processing temperature of 150C. Accordingly, condensation of process gases will not occur and the resultant particles therefrom will not form.

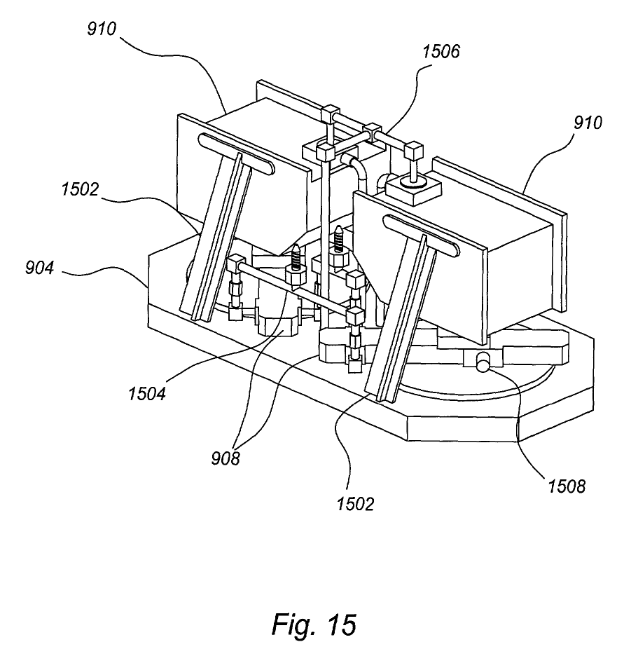

Returning to FIG. 9 and also seen in FIG. 15 are details of the gas distribution system 906. As the chamber 106 comprises two processing regions 806/808 it will be understood that there are dual components for each of the single components described here and as seen in the accompanying figures. Specifically, the gas distribution system 906 further comprises an introducing conduit 908 connected to the lid 904. Disposed above and connected to the introducing conduit 908 is the plasma cleaning unit 910. A bracket 1502 retains the plasma cleaning unit 910 in place on the lid 904. A plurality of gas lines 1504 are plumbed to the introducing conduit 908 and provided with T-fittings so as to facilitate connection of the chamber 106 to process gas sources as described in greater detail below. Additional gas lines 1506 are plumbed to the plasma cleaning unit 910 and provided with T-fittings so as to facilitate connection of the plasma cleaning unit 910 to cleaning gas sources as described in greater detail below. The introducing conduit 908 is further provided with at least two valves 1508 (only one depicted) so as to facilitate control of process gases into the processing region 806/808. Such valves are preferably electrically controllable valves to precisely meter the amount of gas introduced to the processing region 806/808. Examples of electrically actuated valves include those available from Fujiken. Valves capable of precise high speed injection or dosing of process gases may also be pneumatically controlled. The plasma clean unit 910 is plumbed to a cleaning gas source (i.e. one of the sources described in detail below) and is preferably plumbed to an NF3 source. An N2 purge line is also connected to the plasma clean unit 910 so that there is continuous purge of the unit 910 to prevent trapping of NH3 in a dead volume during ALD processing. Moreover, the proximity of the unit 910 to the top of the lid is advantageous in that it raises the efficiency of the cleaning operation.

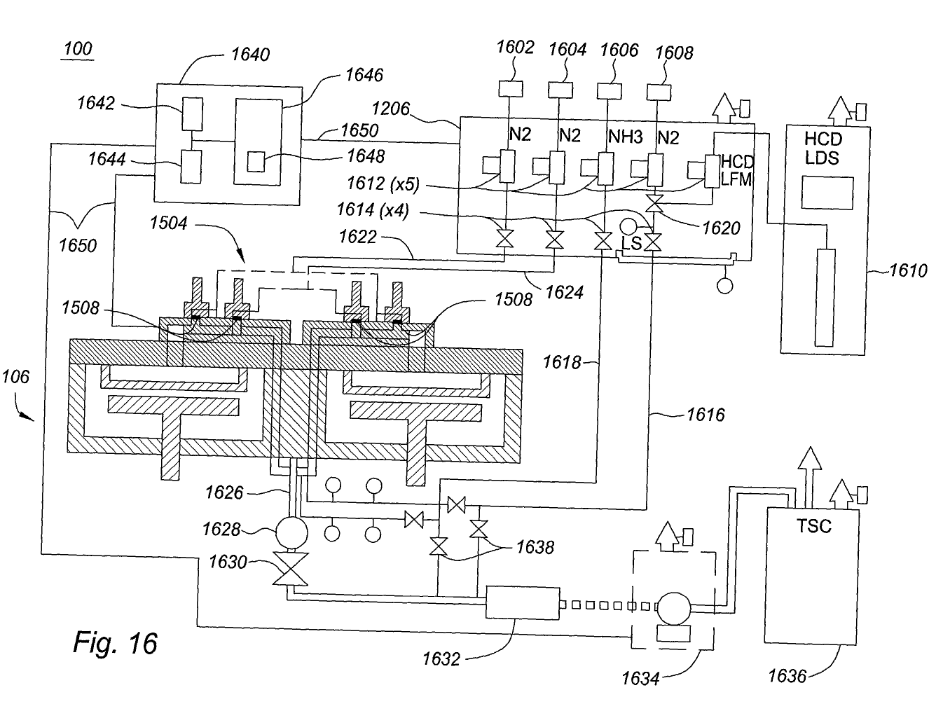

FIG. 16 depicts a schematic diagram of the processing system 100 detailing the connections of the gas sources to the chamber 106. Specifically, a plurality of gas sources 1602-1610 are provided from the facility that houses the system 100 and are plumbed through the appropriate portion of the modular frame 108 and then into gas panel 1206. Such sources may include a first reactant gas purge 1602, a second reactant gas purge 1604, a first reactant gas 1610, a second reactant gas 1606 and a carrier gas for one of the reactant gases 1608. Appropriately positioned liquid flow meters 1612 and valves 1614 plumbed between the gas sources and the chamber 106 meter the gases. Preferably, the first reactant gas is provided to the chamber 106 by providing a liquefied version of the gas (from liquid source 1610) to one of the liquid flow meters 1612 to an injection valve 1620 to first reactive gas line 1616 to one of the valves 1508 at the introducing conduit 908. Similarly the second reactant gas is provided to the chamber via second reactant gas source 1606, an LFM 1612, a valve 1614, second reactant gas line 1618 and the other of the valves 1508 at the introducing conduit 908. If a carrier gas is used to deliver reactant gases from the reactant gas source 1606 1610, preferably the same gas is used as a carrier gas and a purge gas (i.e. argon or nitrogen gas is used as a carrier gas and a purge gas and dichlorosilane (SiH₂Cl₂) is used as a reactant gas or nitrogen is used as a carrier gas and a purge gas and vaporized hexachlorodisilane (Si₂Cl₆) is used as a reactant gas).

Programmable logic controllers may be coupled to the valves 1508 to control actuation of same to synchronize the injection dosing required or desired for a particular deposition cycle. High speed, electrically actuated valves may provide pulses of gases in time periods as low as about 0.005 seconds. An electrically actuated valve typically requires the use of a driver coupled between the valve and the programmable logic controller.

Each valve 1508 may be a zero dead volume valve to enable flushing of a reactant gas from the delivery lines 1616/1618 when the valve is closed. That is, each of the process gases can be purged (at the lid 904) via first 1622 and second 1624 reactive gas purge lines plumbed from their respective purge gas sources 1602, 1604, LFM's 1612, valves 1614 to the chamber 904. For example, the purge lines 1622 and 1624 may be positioned adjacent the valves 1508. When the valves 1508 are closed, the purge lines 1602/1604 may provide a purge gas to flush the reactant gas lines 1616/1618. A zero dead volume valve as used herein is defined as a valve which has negligible dead volume (i.e., not necessarily zero dead volume.)

Common exhaust channel 1019 (of FIG. 11) is connected to hot exhaust line 1626. Further downstream to complete the exhausting of effluent from the chamber 106 is a hot throttle valve 1628, a hot isolation valve 1630, a cold trap 1632, a pump 1634 and a TCS 1636. Additional reactant to exhaust line valves 1638 are provided to assist in purging as necessary.

The chamber lid 904 may include cooling elements and/or heating elements (such as embedded heater 1652) depending on the particular gas being delivered therethrough. Controlling the temperature of the chamber lid 904 may be used to prevent gas decomposition, deposition, or condensation on the chamber lid 904. For example, heat transfer fluid channels may be formed in the chamber lid 904 to cool the chamber lid 904. In another example, heating elements may be embedded or may surround components of the chamber lid 904 to heat the chamber lid 904. In one embodiment, components of the chamber lid 904 may be individually heated or cooled. The cap may be maintained at one temperature range and the chamber lid may be maintained at another temperature range. The chamber lid 904 may be made of stainless steel, aluminum, anodized aluminum, nickel-plated aluminum, nickel, or other suitable materials compatible with the processing to be performed.

Returning to FIG. 16, a control unit 1640, such as a programmed personal computer, work station computer, or the like, may be coupled to the chamber 106 to control processing conditions. For example, the control unit 1640 may be configured to control flow of various process gases and purge gases from gas sources 1602-1610 through the valves 1614, 1508, 1630, 1638 and the like during different stages of a substrate process sequence. Illustratively, the control unit 1640 comprises a central processing unit (CPU) 1642, support circuitry 1644, and memory 1646 containing associated control software 1648.

The control unit 1280 may be one of any form of general purpose computer processor that can be used in an industrial setting for controlling various chambers and sub-processors. The CPU 1642 may use any suitable memory 1646, such as random access memory, read only memory, floppy disk drive, hard disk, or any other form of digital storage, local or remote. Various support circuits may be coupled to the CPU 1642 for supporting the chamber 106. The control unit 1640 may be coupled to another controller that is located adjacent individual chamber components, such as the programmable logic controllers (not shown) of the valves 1508. Bi-directional communications between the control unit 1640 and various other components of the chamber 106 are handled through numerous signal cables collectively referred to as signal buses 1650, some of which are illustrated in FIG. 16. In addition to control of process gases and purge gases from gas sources 1602-1610 and from the programmable logic controllers of the valves 1614, 1508, 1630, 1638 and the like, the control unit 1640 may be configured to be responsible for automated control of other activities used in wafer processing—such as wafer transport, temperature control, chamber evacuation, among other activities, some of which are described elsewhere herein.

The chamber body 902 defines a plurality of vertical gas passages for each reactant gas and cleaning gas suitable for the selected process to be delivered in the chamber through the gas distribution system. Gas inlet connections 1041 are disposed at the bottom of the chamber 106 to connect the gas passages formed in the chamber wall to the gas inlet lines 1039 (see FIG. 10). An o-ring is provided around each gas passage formed through the chamber wall on the upper surface of the chamber wall to provide sealing connection with the lid as shown in FIG. 11.

While this is a preferred gas distribution system, the gases from the remote plasma source can be introduced into the processing regions through a port provided through the chamber wall. In addition, process gases could be delivered through any gas distribution system which is presently available, such as the gas distribution system available from Applied Materials, Inc. of Santa Clara, Calif.

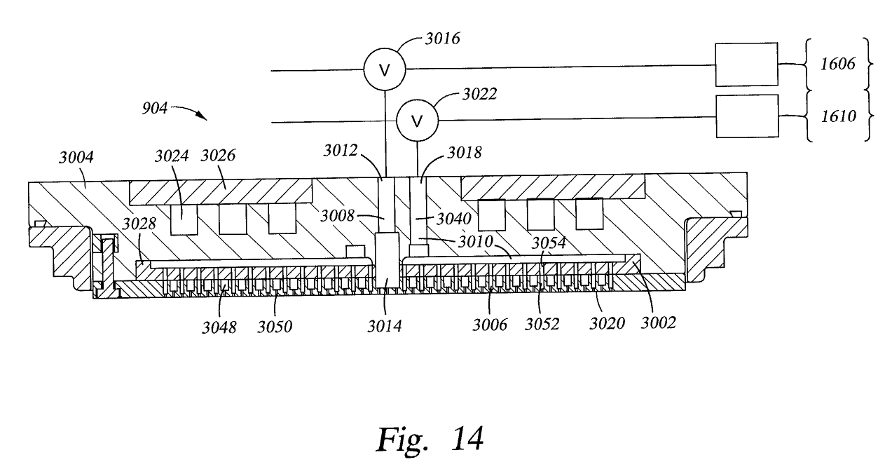

FIG. 14 depicts a more detailed version of the lid 904 originally seen in FIGS. 10 and 13. The lid 904 is disposed at an upper portion of the chamber body 902 to provide two reactant gas flows distributed in a substantially uniform manner over a wafer W. The two reactant gas flows are delivered in separate and discrete paths through the lid 904. Specifically, the lid 904 comprises a lid body 3004 having a lower surface recess 3028. A gas disperser 3002 is disposed in the lower surface recess 3028. A dual-channel faceplate 3006 is positioned below the gas disperser 3002. The lid 904 provides two gas flows through two discrete paths to a processing region 806 or 808 defined between the faceplate 3006 and the wafer support 1028.

The lid body 3004 as used herein is defined as a gas manifold coupling gas sources to the chamber 106. The lid body 3004 comprises a first gas channel 3008 and a second gas channel 3010 providing two separate paths for the flow of gases through the gas disperser 3002. The first gas channel 3008 comprises a first gas input 3012 and a first gas outlet 3014. The first gas input is adapted to receive a first gas from the first reactive gas source (i.e., source 1606 or a combination thereof) through valve 3016. The first gas outlet 3014 is adapted to deliver the first reactive gas to the top of the processing region 806/808. The second gas channel 3010 of the lid body 3004 comprises a second gas input 3018 and a second gas outlet 3020. The second gas input 3018 is adapted to receive a second reactive gas from a second gas source (i.e., source 1610 or a combination thereof through valve 3022. The second gas outlet 3020 is adapted to deliver the second gas to the processing region 806/808. The term “gas” as used herein is intended to mean a single gas or a gas mixture. Gas sources as described above may be adapted to store a gas or liquid precursor in a cooled, heated, or maintained at ambient environment. The gas lines fluidly coupling the gas sources 1606 and 1610 to the gas inputs 3012, 3018 may also be heated, cooled, or at ambient temperature. More specifically and in a preferred embodiment of the invention, reactive gas line 1616 is heated to prevent condensation of a vaporized reactive gas such as, for example, HCD.

The lid body 3004 may further comprise one or more temperature fluid control channels 3024 to control the temperature of the lid 904 by providing a cooling fluid or a heating fluid to the lid body 3004 depending on the particular process being performed in the chamber 106. The top plate 3026 provides the upper enclosure for the temperature fluid control channel 3024. Controlling the temperature of the lid 904 may be used to prevent gas decomposition, deposition, or condensation within the lid 904.

Referring to FIG. 14, the gas disperser 3002 has a plurality of holes 3054 to accommodate a gas flow therethrough from the second gas channel 3010 through a plurality of holes 3052 in the faceplate 3006 to the processing region 806/808. Similarly, the faceplate 3006 has a plurality of grooves 3048 that fluidly communicate with first gas outlet 3014 and a plurality of holes 3050 to accommodate a gas flow therethrough to the processing region 806/808. Such a design permits a dual-channel feature of the faceplate design. For example, gases flowing through the holes 3050 and 3052 can be maintained at a temperature range of approximately 70-300° C. for adequate thermal control of same. In one specific embodiment, the diameter of holes 3050, 3052 and 3054 are between about 10 mils and about 100 mils and there are in the range of approximately 100-2000 such holes. No mixing of the gases behind the faceplate and better temperature control of the gases results in better film formation. Additionally, such a configuration allows for easy cyclic processing (i.e., switching from ALD to CVD and back without the need to change faceplates). Moreover, the design of the faceplate of the subject invention shortens the flowpath of reactant gases which facilitates rapid purging during ALD operations. Examples of temperature ranges for gases used in the system are in the range of approximately 50° C.-150° C. Carrier gases (which assist in the movement of the process gases are preferably selected from the group consisting of nitrogen, argon and helium. Keeping the overall faceplate 3006 at a temperature in a range of approximately 130-150° C. minimizes the possibility of forming particulate ammonia chloride which is undesirable.

The above-presented and discussed figures depict various internal and external views of the chamber body 902 and processing regions 806,808 that facilitate ALD (chemisorption) and CVD processes in the same environment. That is, the design of the lid and the dual channel faceplate minimize volumes in which process gases may become trapped when not in the processing regions 806,808. Accordingly, purging of such areas is easily accomplished and process recipes for other processes (for example CVD immediately following ALD) does not readily introduce particles, residues or otherwise result in slower throughput than previously possible in the semiconductor fabrication industry. The chamber liner 1027 is kept at temperature at or above 150C to prevent formation of ammonia chloride (a result of an interaction between HCD and ammonia). The purge gas channel 1310 allows for a flow of purge gas from the lid 904 so as to prevent depositions from forming in the faceplate vicinity (since the temperature of the lid is only 70C). There are also provisions for a bottom purge gas flow to prevent deposition between the liner 1027 and chamber 106. Purge provisions also exist for slit valves presented in earlier figures. Additionally, the tandem process chambers 106 can be configured to perform dedicated processes (i.e., 2 chambers for CVD only and 1 chamber for ALD only) depending upon desired throughput.

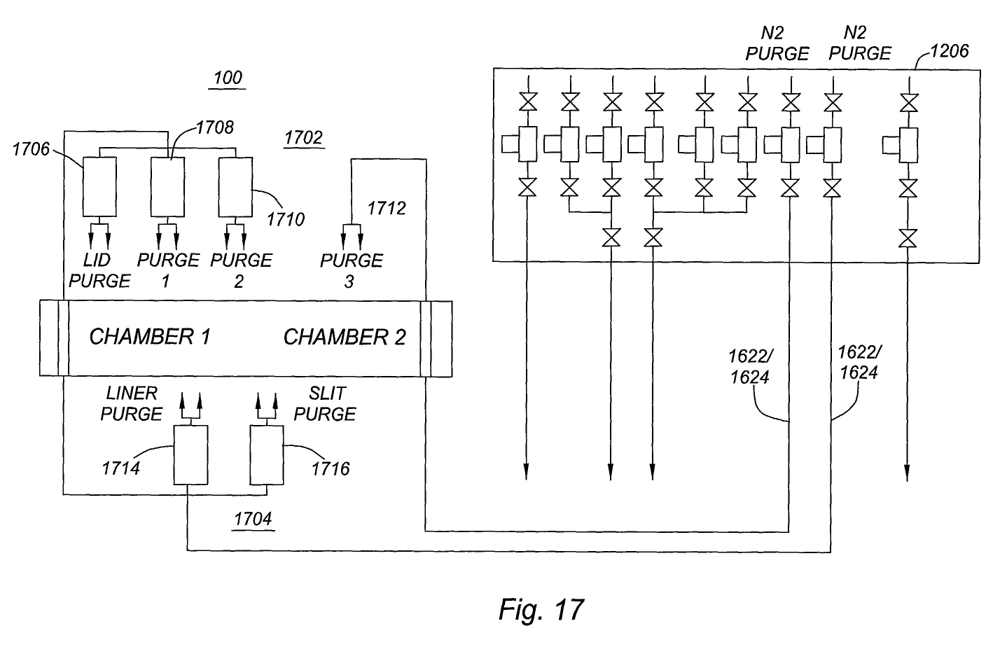

FIG. 17 depicts a schematic diagram of the system 100 detailing the purge lines. Specifically, it was above-discussed that various purge lines exist in the system to facilitate purging of portions of the system 100 thereby improving the efficiency of the deposition processes and overall film quality. The purge lines can be broken down into two subsystems: a lid purge subsystem 1702 and a liner purge subsystem 1704. The lid purge subsystem 1702 originates at one of the nonreactive gas sources (i.e. one of sources 1602, 1604 or 1608) and is regulated by one or more MFCs and valves at the gas panel 1206 as discussed earlier. The source is connected to a purge line (i.e. one of gas lines 1622, 1624 or another similarly routed gas line and split at the lid 904. Specifically, the purge line is branched into a plurality of flow restrictors (a first flow restrictor 1706, a second flow restrictor 1708 and a third flow restrictor 1710 respectively) to create part of the lid purge subsystem 1702. The first flow restrictor 1706 is connected to one of the T-fittings that branch out and connect to the faceplate purge ports 1320. The second flow restrictor 1708 is connected to one of the T-fittings that branch out and connect to each of the valves 1508 that meters the flow of the second reactive gas (e.g. NH3) to each of the processing regions 806/808. The third flow restrictor 1710 is connected to one of the T-fittings that branch out and connect to the plasma cleaning unit 910. A separate gas line 1622/1624 from the gas line containing the three flow restrictors 1706, 1708 and 1710, also comprises the lid purge subsystem 1702. That is, this separate gas line is connected from a purge gas source to the valves 1508 that meter the flow of the first reactive gas (e.g. HCD) to each of the processing regions 806/808 from the lid 904 at outlet 1712. In this way, greater selectivity of the purging of various portions of the system is easily accomplished. Additionally, as the valves are zero dead volume (or close thereto) the purging can be effected rapidly thereby increasing processing efficiency.

The liner purge subsystem 1704 operates in substantially the same manner and is described in detail as follows. The liner purge subsystem 1704 originates at one of the non-reactive gas sources (i.e. one of sources 1602, 1604 or 1608) and is regulated by one or more MFCs and valves at the gas panel 1206 as discussed earlier. The source is connected to a purge line (i.e. one of gas lines 1622, 1624 or another similarly routed gas line that has the first, second and third flow restrictors already connected thereto) and split 2 more ways at the bottom of the chamber 106. Specifically, the purge line is branched into a fourth flow restrictor 1714 and a fifth flow restrictor 1716 respectively. The fourth flow restrictor 1714 is connected to one of the T-fittings that branch out and provide a purge gas between the liner 1027 and chamber wall 1014 as described above with respect to FIG. 13. The fifth flow restrictor 1716 is connected to one of the T-fittings that branch out and connect to one or more slit valves (contained in process chamber wafer passages 810. In this way, effective purging of various portions of the system not specifically related to the process gas distribution and flow is easily accomplished and the chamber is further protected from undesirable contaminants.

Heater Pedestal

FIG. 10 shows a heater pedestal 1028 which is movably disposed in each processing region 806, 808 by a stem 1026 which is connected to the underside of a support plate and extends through the bottom of the chamber body 902 where it is connected to a drive system 1003. Preferably the heater pedestal 1028 is fabricated from ceramic and comprises at least two embedded heater electrodes (i.e. a first heater electrode 1054 and a second heater electrode 1056). Each of the electrodes 1054 and 1056 is electrically connected to either of AC boxes 116 or 118 described above to obtain the necessary electrical power for heating. The electrodes may be configured in a concentric pattern (i.e. the first heater electrode 1054 is an inner electrode and a second heater electrode 1056 is an outer electrode). In this manner, the heater pedestal has a dual zone configuration to better compensate for nonuniformities in temperature in the processing region 806/808.

The drive system 1003 includes linear electric actuators made by Industrial Device Corporation located in Novato, Calif. The heater assembly is raised and lowered by moving the transfer housing up or down to a process, clean, lift and release position. The transfer housing is connected to the actuator on one side and a linear slide on the other through a carriage plate. Alternatively, the drive system 1003 includes a motor and reduction gearing assembly suspended below the chamber 106 and connected to a drive belt to a conformable coupling and lead screw assembly.

Wafer Positioning Assembly

The stem 1026 moves upwardly and downwardly in the chamber to move the heater pedestal 1028 to position a wafer thereon or remove a wafer therefrom for processing. A wafer positioning assembly includes a plurality of support pins 1050 which move vertically with respect to the heater pedestal 1028 and are received in bores 1052 disposed vertically through the pedestal. As the drive system 1003 lifts and lowers the pedestal heater 1028, the support pins 1050 will be moved upwardly and downwardly in each processing region 806, 808 to control the height of a substrate or wafer (W) on the heater pedestal 1028. In a preferred embodiment, each heater pedestal comprises three support pins 1050 that contact the bottom of the chamber to alter the height of the substrate W.

Vacuum System and Chamber Pumps

The vacuum control system for the processing system 100 of the present invention may include a plurality of vacuum pumps in communication with various regions of the system, with each region having its own setpoint pressure. However, the transfer of wafers from one chamber or region to another chamber or region requires the opening of slit valves which allow the environments of the communicating regions to mix somewhat and the pressures to equalize.

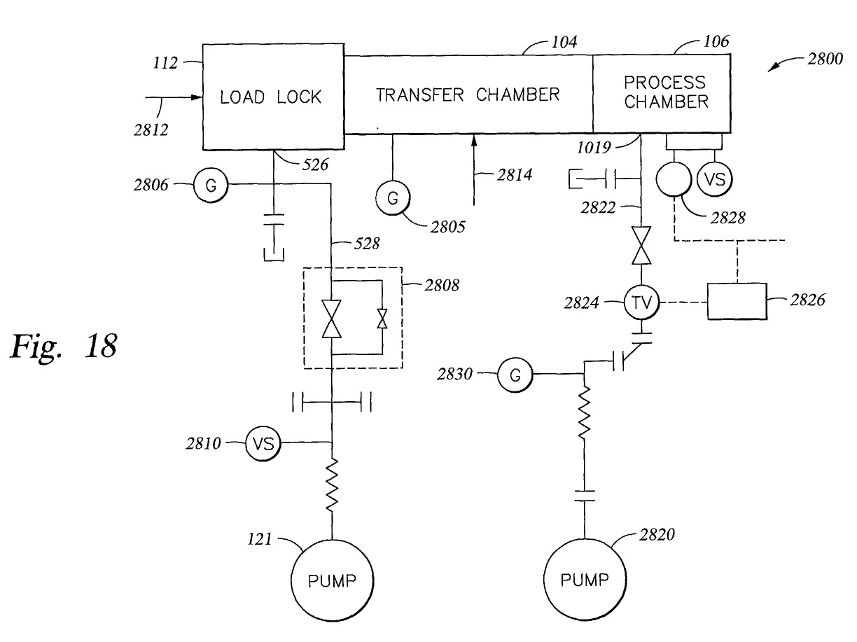

FIG. 18 shows a schematic diagram of the vacuum system 2800 of the present invention. The loadlock chamber 112 and the transfer chamber 104 preferably share a vacuum pump 121 (see also FIG. 5) mounted adjacent the loadlock chamber and the transfer chamber. The loadlock chamber 112 is pumped down from atmosphere by pump 121 through exhaust port 526 disposed through the body of the loadlock chamber. The vacuum pressure in the transfer chamber 104, as indicated by pressure gauge 2805, is provided by communication with the loadlock chamber 112 so that the pressure in the transfer chamber is always equal to or greater than the pressure in the loadlock chamber and any particles present in the loadlock chamber will not be drawn into the transfer chamber 104. Exhaust port 526 in loadlock chamber 112 is connected to pump 121 via exhaust line 528. A pressure gauge 2806 is positioned along exhaust line 528 upstream from an isolation valve 2808 to monitor the pressure in the loadlock chamber at any given time. Isolation valve 2808 is located in exhaust line 528 between the pressure gauge 2806 and the pump 121 to regulate the pressure in the loadlock chamber. A vacuum switch 2810 is also provided in communication with the exhaust line between the isolation valve 2808 and the pump 121. The pump 121 is preferably a roughing pump, but depending on the application may be any type of pump such as a turbomolecular pump, a cryogenic pump or the like. Gas vent lines 2812, 2814 are connected to the loadlock chamber 112 and the transfer chamber 104, respectively, to provide a vent gas, such as nitrogen, into these chambers.

Process chambers 106 are connected to a heated pump 2820, such as a roughing pump, cryogenic pump or turbomolecular pump, via exhaust port 1019 (of FIG. 11) and exhaust line 2822. A heated throttle valve 2824, or the like, is located in the exhaust line to regulate the pressure in the processing regions 806, 808 of chambers 106 during operation. A heated valve controller 2826, preferably a part of the system controller, provides a control signal to the heated throttle valve 2824 based upon the pressure indicated by the vacuum gauge 2830. Preferably, an exhaust port 1019 is in communication with each processing region (FIG. 11) and an exhaust line from each processing region tees into a single exhaust line 2822 which is connected to the pump 2820.

According to one aspect of the present invention, the slit valves in communication with the transfer chamber 104 and the vacuum controllers of each chamber 106 and the loadlock chamber 112 are operated in a manner that reduces the amount of contaminants entering the transfer chamber from either the loadlock chamber or any of the chambers 106. The invention requires the pressure in the loadlock chamber to be greater than or equal to, preferably greater than, the pressure in an adjacent chamber or region prior to opening the slit valve that will provide communication therebetween. The loadlock pressure should only be greater than atmospheric when open to the front end. The pressure should be lower than the transfer chamber pressure when opening to transfer in vacuum. It is particularly important that the transfer chamber 104 be at a high relative pressure when placed in communication with a process chamber, because the contaminant levels can be particularly great. For example, where the setpoint pressure in a processing chamber 106 is about 10⁻³ torr, the pressure in the transfer chamber should be greater than or equal to 10⁻³ torr, most preferably greater than about 10⁻² torr, before opening the slit valves to transfer wafers into or out of the chamber 106.

RF Power Supplies

An Remote Plasma Source (RPS) power delivery system is used for each processing region 806, 808 with one system connected to each gas distribution system. A 400 KHz Astron MKS RF generator is mounted on the back end of the system for each chamber. This RF generator is designed for use with a fixed match and regulates the power delivered to the load, eliminating the concern about forward and reflected power.

Programming

The system controller (control unit 1640 of FIG. 16) operates under the control of a computer program stored on the hard disk drive of a computer. The computer program dictates the process sequencing and timing, mixture of gases, chamber pressures, RF power levels, susceptor positioning, slit valve opening and closing, wafer heating and other parameters of a particular process. The interface between a user and the system controller is preferably via a CRT monitor and lightpen which is mounted to some part of the system 100 (i.e., the front end staging area 102 or modular process chamber frames 108. In a preferred embodiment two monitors are used, one monitor mounted in the clean room wall for the operators and the other monitor behind the wall for the service technicians. Both monitors simultaneously display the same information but only one lightpen is enabled. The lightpen detects light emitted by the CRT display with a light sensor in the tip of the pen. To select a particular screen or function, the operator touches a designated area of the display screen and pushes the button on the pen. The display screen generally confirms communication between the lightpen and the touched area by changing its appearance, i.e. highlight or color, or displaying a new menu or screen.

A variety of processes can be implemented using a computer program product that runs on, for example, the system controller. The computer program code can be written in any conventional computer readable programming language such as for example 68000 assembly language, C, C++, or Pascal. Suitable program code is entered into a single file, or multiple files, using a conventional text editor, and stored or embodied in a computer usable medium, such as a memory system of the computer. If the entered code text is in a high level language, the code is compiled, and the resultant compiler code is then linked with an object code of precompiled library routines. To execute the linked compiled object code, the system user invokes the object code, causing the computer system to load the code in memory, from which the CPU reads and executes the code to perform the tasks identified in the program.

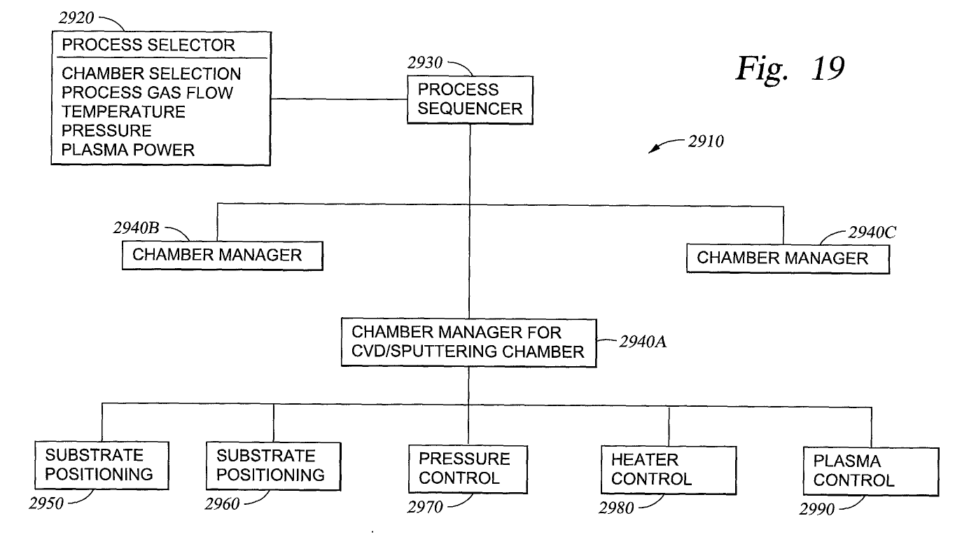

FIG. 19 shows an illustrative block diagram of a preferred hierarchical control structure of an exemplary computer program 2910. A user enters a process set number and process chamber number into a process selector subroutine 2920 in response to menus or screens displayed on the CRT monitor by using the lightpen interface. An example of the subroutines and implementing hardware for same is the above-described DNET digital signal processor. The process sets provide predetermined sets of process parameters necessary to carry out specified processes, and are identified by predefined set numbers. The process selector subroutine 2920 identifies (i) the desired process chamber, and (ii) the desired set of process parameters needed to operate the process chamber for performing the desired process. The process parameters for performing a specific process relate to process conditions such as, for example, process gas composition and flow rates, temperature, pressure, plasma conditions such as RF bias power levels and magnetic field power levels, cooling gas pressure, and chamber wall temperature and are provided to the user in the form of a recipe. The parameters specified by the recipe are entered in any conventional manner, but most preferably by utilizing the lightpen/CRT monitor interface.

Electronic signals provided by various instruments and devices for monitoring the process are provided to the computer through the analog input and digital input boards of the system controller. Any conventional method of monitoring the process chambers can be used, such as polling. Furthermore, electronic signals for operating various process controllers or devices are output through the analog output and digital output boards of the system controller. The quantity, type and installation of these monitoring and controlling devices may vary from one system to the next according to the particular end use of the system and the degree of process control desired. The specification or selection of particular devices, such as the optimal type of thermocouple for a particular application, is known by persons with skill in the art.

A process sequencer subroutine 2930 comprises program code for accepting the identified process chamber number and set of process parameters from the process selector subroutine 2920, and for controlling operation of the various process chambers. Multiple users can enter process set numbers and process chamber numbers, or a user can enter multiple process chamber numbers, so the sequencer subroutine 2930 operates to schedule the selected processes in the desired sequence. Preferably, the process sequencer subroutine 2930 includes program code to perform the steps of (i) monitoring the operation of the process chambers to determine if the chambers are being used, (ii) determining what processes are being carried out in the chambers being used, and (iii) executing the desired process based on availability of a process chamber and type of process to be carried out. When scheduling which process is to be executed, the sequencer subroutine 2930 can be designed to take into consideration the present condition of the process chamber being used in comparison with the desired process conditions for a selected process, or the “age” of each particular user entered request, or any other relevant factor a system programmer desires to include for determining the scheduling priorities.

Once the sequencer subroutine 2930 determines which process chamber and process set combination is going to be executed next, the sequencer subroutine 2930 causes execution of the process set by passing the particular process set parameters to a chamber manager subroutine 2940a-c which controls multiple processing tasks in a process chamber 106 according to the process set determined by the sequencer subroutine 2930. For example, the chamber manager subroutine 2940 comprises program code for controlling ALD and CVD process operations in the process chamber 106. The chamber manager subroutine 2940 also controls execution of various chamber component subroutines which control operation of the chamber component necessary to carry out the selected process set. Examples of chamber component subroutines are wafer positioning subroutine 2950, process gas control subroutine 2960, pressure control subroutine 2970, heater control subroutine 2980, and plasma control subroutine 2990. Those having ordinary skill in the art will recognize that other chamber control subroutines can be included depending on what processes are desired to be performed in the process chamber 106. In operation, the chamber manager subroutine 2940a selectively schedules or calls the process component subroutines in accordance with the particular process set being executed. The chamber manager subroutine 2940a schedules the process component subroutines similarly to how the sequencer subroutine 2930 schedules which process chamber 106 and process set is to be executed next. Typically, the chamber manager subroutine 2940a includes steps of monitoring the various chamber components, determining which components need to be operated based on the process parameters for the process set to be executed, and causing execution of a chamber component subroutine responsive to the monitoring and determining steps.

While the foregoing is directed to the preferred embodiment of the present invention, other and further embodiments of the invention may be devised without departing from the basic scope thereof. The scope of the invention is determined by the claims which follow.

What is claimed is:

1. An apparatus for processing wafers comprising:
a process chamber having two distinct processing regions;
a lid disposed over and the process chamber;
a substrate support disposed in each of the processing regions; and
a chamber liner circumscribing each of the substrate supports and extending along the bottom of the chamber thereby defining a gap between the chamber and the liner.

2. The apparatus of claim 1 wherein the liner sealingly fits about a stem supporting the substrate support.

3. The apparatus of claim 1 wherein the liner is of multi-piece construction.

4. The apparatus of claim 3 wherein the liner further comprises a bottom piece and a top piece.

5. The apparatus of claim 4 wherein the bottom piece fits about a stem of the substrate support and radially extends outward therefrom.

6. The apparatus of claim 4 wherein the top piece connects to the bottom piece at a right angle and circumscribes the substrate support.

7. The apparatus of claim 1 wherein the liner further comprises at least one vacuum exhaust port.

8. The apparatus of claim 1 wherein a purge gas is flowed in the gap defined by the liner and the chamber.

9. The apparatus of claim 1 further comprising a plasma cleaning unit disposed on top of the lid.

10. The apparatus of claim 9 wherein the plasma cleaning unit is connected to a cleaning gas source and a purge gas source.

11. The apparatus of claim 10 where the cleaning gas source is NF3 and the purge gas source is N2.

12. The apparatus of claim 10 wherein the purge gas source continuously provides purge gas to the plasma cleaning unit.

13. The apparatus of claim 1 wherein the lid further comprises:
a lid body;
a gas distributor disposed in a recess in the lid body; and
a faceplate disposed below the gas distributor.

14. The apparatus of claim 13 wherein the lid further comprises openings to allow connection of the lid to two reactant gases.

15. The apparatus of claim 14 wherein the openings comprise a first channel fluidly connected to a first set of openings and a second channel fluidly connected to a second set of openings wherein neither the first and second channels nor the first and second set of openings are fluidly interconnected.

16. The apparatus of claim 13 wherein the lid body further comprises coolant passages disposed therein.

17. The apparatus of claim 15 wherein the first set of openings is in the range of approximately 10-100 mils.

18. The apparatus of claim 15 wherein the second set of openings is in the range of approximately 10-100 mils.

19. The apparatus of claim 13 further comprising a purge gas channel defined by a circumferential edge of the faceplate and the chamber.

20. An apparatus for processing wafers, comprising:
(a) a loadlock chamber;
(b) a transfer chamber communicating with the loadlock chamber;
(c) one or more processing chambers communicating with the transfer chamber, each processing chamber defining a plurality of isolated processing regions therein;
(d) a lid disposed on each of the one or more processing chambers, the lid having first and second opposed surfaces and two or more reactant gas channels extending from the first surface,
(e) a gas distribution system containing a plasma cleaning unit in close proximity to the first surface; and
(f) a dual-channel faceplate coupled to the lid to facilitate dispersion of at least two reactant gases wherein the gases are not in fluid communication until exiting the faceplate.

21. The apparatus of claim 20 further comprising a wafer staging area.

22. The apparatus of claim 21 wherein the staging area includes one or more wafer cassette turntables disposed thereon.

23. The apparatus of claim 22 further comprising a second wafer handling member disposed in the staging area.

24. The apparatus of claim 20 wherein the first wafer handling member comprises a plurality of wafer handling blades for concurrently transporting a plurality of wafers between the loadlock chamber and the one or more processing chambers.

25. The apparatus of claim 24 wherein the plurality of wafer handling blades are coplanar.

26. The apparatus of claim 21 further comprising a wafer pedestal disposed in each processing region.

27. The apparatus of claim 26 wherein each wafer pedestal includes a heating member disposed therein.

28. The apparatus of claim 27 wherein the heating member is a resistive heating element.

29. The apparatus of claim 27 wherein the heating member is a lamp.

30. The apparatus of claim 20, wherein a common purge gas source is coupled to various locations of the lid and wherein separate reactant gas sources are coupled to each gas conduit.
